(19) United States
(12) Patent Application Publication
(10) Pub. No.: US 2007/0221130 A1
(43) Pub. Date: Sep. 27, 2007

(54) Substrate Processing Apparatus

(75) Inventors: Toshihisa Nozawa, Hyogo (JP); Tamaki Yuasa, Hyogo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Tokyo Electron Limited, Tokyo (JP)

(21) Appl. No.: 11/597,523

(22) PCT Filed: May 23, 2005
(86) PCT No.: PCT/JP05/09372

§ 371 Date: Nov. 27, 2006

(30) Foreign Application Priority Data
May 27, 2004 (JP) 2004-158130

(51) Int. Cl. C23C 16/44

(52) U.S. Cl. 118/719

(57) ABSTRACT

The present invention has the object of improving the efficiency of cleaning in a substrate processing apparatus. Thus, the present invention uses a substrate processing apparatus, comprising: a processing vessel holding therein a substrate to be processed; gas supply means for supplying a gas for processing into said processing vessel; a stage provided in the processing vessel for holding said substrate to be processed; a shielding plate dividing a space inside said processing vessel into a first space and a second space, wherein there are provided: a first evacuation path for evacuating said first space; and a second evacuation path for evacuating said second space.

### TECHNICAL FIELD

The present invention relates to a substrate processing apparatus for processing a substrate to be processed.

### BACKGROUND ART

In a processing vessel carrying out film forming processing in a substrate processing apparatuses used for processing a substrate to be processed, there are cases in which the state of inner wall surface of the processing vessel causes a problematic influence on the substrate processing.

For example, in the case of conducting film formation by using a sputtering method or CVD (chemical vapor deposition) method, there is caused film formation not only on the substrate to be processed but also on the inner wall surface of the processing vessel, while exfoliation of the film from the inner wall surface may cause formation of particles, or the like. Thereby, there has been caused a problem of decrease of yield, or the like.

Thus, there has been a case of providing a protective member of plate-like form called shielding plate for the purpose of protecting the inner wall surface of the processing vessel. Thereby, attempts have been made to suppress film exfoliation from the shielding plate or particle formation. These includes the attempt of suppressing the particle formation by replacing the shielding plate, the attempt of reducing the amount of the film adhered on the shielding plate by heating the shielding plate, the attempt of increasing the efficiency of cleaning of the shielding plate by heating the shielding plate, or the like.
Patent Reference 1 Japanese Laid-Open Patent Application 6-151321 Official Gazette

### DISCLOSURE OF THE INVENTION

When the shielding plate is disposed in the processing vessel, a gap is formed between the shielding plate and the processing vessel, and thus, there can be a case in which the film forming gas used for the substrate processing invades into such a gap. When this occurs, there is caused formation of deposits in such a gap, while such deposits may become the source of the particles.

In the case attempt is made to remove such deposits formed in the gap between the shielding plate and the processing vessel by a cleaning process that uses an plasma-activated cleaning gas, however, it is difficult to supply the cleaning gas thoroughly to such a gap and there arises a problem of poor cleaning efficiency. Thus, there is a problem that removal of the deposits is difficult.

Thus, it is the object of the present invention to provide a novel and useful substrate processing apparatus wherein the foregoing problems are eliminated.

A more specific object of the present invention is to improve the cleaning efficiency of deposits in a processing vessel of a substrate processing apparatus in which a shielding plate is provided.

The present invention resolves the foregoing problems by a substrate processing apparatus, comprising: a processing vessel holding therein a substrate to be processed; gas supplying means for supplying a gas for processing into the processing vessel; a stage provided in the processing vessel for holding the substrate to be processed; a shielding plate dividing a space inside the processing vessel into a first space and a second space, characterized in that there are provided a first evacuation path for evacuating the first space and a second evacuation path for evacuating the second space.

According to the present invention, it becomes possible to improve the cleaning efficiency of the substrate processing apparatus.

### BRIEF DESCRIPTION OF THE DRAWINGS

FIG. 1 is a schematic cross-sectional diagram of a substrate processing apparatus according to Embodiment 1 of the present invention;

FIG. 2 is a plan view of a slot plate used with the substrate processing apparatus of FIG. 1;

FIG. 3 is a schematic cross-sectional diagram of a substrate processing apparatus according to Embodiment 2 of the present invention.

### BEST MODE FOR IMPLEMENTING THE INVENTION

Next, embodiment of the present invention will be explained with reference to the drawings.

### EMBODIMENT 1

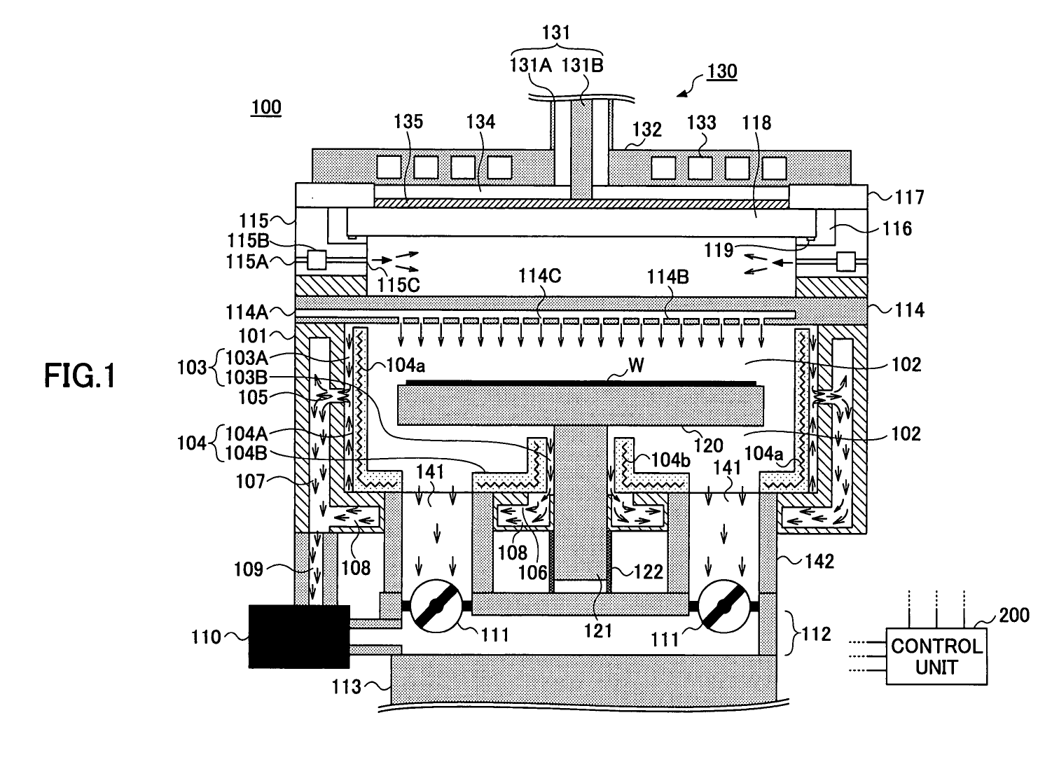

FIG. 1 is a schematic cross-sectional diagram showing a substrate processing apparatus 100 according to Embodiment 1 of the present invention schematically. Referring to FIG. 1, the substrate processing apparatus 100 has a processing vessel 101 formed of a metal such as Al, for example, wherein a stage 120 holding a substrate W to be processed is disposed inside the processing vessel 101. The stage 120 is supported by a support part 121 of a cylindrical form, or the like, for example, wherein the support part 121 is fitted into a hole formed at a bottom part of the processing vessel 101 in an erected manner. Thereby, a gap between the substrate processing vessel 101 and the support part 121 is sealed by sealing means 122, which may by a magnetic fluid, vacuum bellows, or the like, for example.

Further, there is disposed a microwave transmission window 118 of generally disk-shaped form and transparent to microwave on the part of the processing vessel 101 corresponding the substrate W to be processed when it is placed on the stage 120. Further, a plasma gas supplying ring 115 of generally ring-shaped form is provided between the microwave transmission window 118 and the processing vessel 101 for supplying a plasma gas into the processing vessel. Further, the microwave transmission window 118 has a construction of making a contact with the plasma gas supplying ring 115 via a transmission window support part 116, wherein the microwave transmission window 118 and the transmission window support part 116 form a hermetic seal at the part where they are contacted with each other by way of a seal ring 119.

Between the microwave transmission window 118 and the stage 120, there is disposed a processing gas supplying part 114 for supplying a processing gas to the interior of the processing vessel. It should be noted that this processing gas supplying part 114 is disposed closer to the stage 120 with regard to the plasma gas supplying ring 115.

According to the substrate processing apparatus 100 of the present embodiment, there is provided a structure that enables substrate processing by supplying a plasma gas from the plasma gas supplying ring 115 (first gas supplying means) into the processing vessel 101 and further supplying a processing gas from the processing gas supplying part 114 (second gas supplying means) also into the processing vessel 101 independently with each other. The plasma gas or processing gas thus supplied is excited into plasma by a microwave introduced via a radial line slot antenna to be described later, and a substrate processing such as film formation is achieved by these plasma-excited gases.

Thus, a plasma gas such as Ar is introduced into the plasma gas supplying ring 115 via a gas inlet 115A, wherein the plasma gas causes diffusion through a gas groove 115B formed inside the gas supplying ring 115 in a generally ring-shaped form.

The plasma gas thus caused diffusion in the gas groove 115B is supplied into the processing vessel 101 via plural plasma gas apertures 115C communicating with the gas groove 115B. Further, the plasma processing gas supplied into the processing vessel 101 reaches a neighborhood of the substrate to be processed via lattice apertures of the processing gas supplying part 114 generally configured in the form of lattice.

The processing gas supplying part 114 is provided in the processing vessel 101 at the part between the microwave transmission window 118 and the substrate W to be processed on the stage 120 in a manner held by a part of the processing vessel 101 so as to face the substrate W to be processed.

The processing gas is introduced into the processing gas supplying part 114 via a processing gas inlet 114A, wherein the processing gas thus introduced causes diffusion through a processing gas passage 114B formed generally in the form of lattice inside the processing gas supplying part 114. The processing gas is then supplied into the processing vessel via gas apertures 114C communicating with the interior of the processing vessel.

Further, it is possible for the plasma gas supplying ring 115 or the processing gas supplying part 114 to supply a cleaning gas for cleaning the interior of the processing vessel, in addition to the gas for the substrate processing, and thus, it is possible to conduct cleaning of the interior of the processing vessel by the cleaning gas. Thus, it is advantageous to use the cleaning gas with plasma excitation for cleaning the interior of the processing vessel according to the needs.

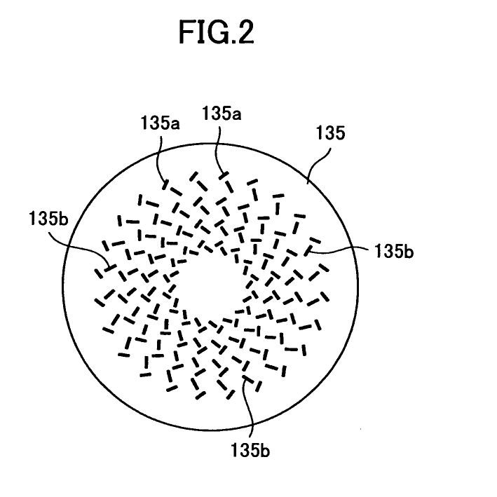

On the microwave transmission window 118, there is provided a radial line slot antenna 130 in intimate contact with the microwave transmission window 118, wherein the radial line slot antenna is constructed from a slot plate 135 of disk shape formed with a large number of slots 135a and 135b shown in FIG. 2, an antenna body 132 of disk-shaped form pressing the slot plate 135, an antenna flange 117 of a generally donuts-shaped form inserted with the slot plate 135, and a retardation plate 134 of a low-loss dielectric such as Al₂O₃, SiO₂ or Si₃N₄ sandwiched between the slot plate 135 and the antenna body 132.

The radial line slot antenna 130 is mounted upon the processing vessel 101 via the plasma gas supplying ring 115, and a microwave of the frequency of 2.45 GHz or 8.3 GHz is supplied to the radial line slot antenna 130 from an external microwave source (not shown) via a coaxial waveguide 131.

The microwave thus supplied is emitted to the interior of the processing vessel 101 from the slots 135a and 135b on the slot plate 135 via the microwave transmission window 118 and causes plasma excitation in the plasma gas supplied from the plasma gas apertures 115C in the space right underneath the microwave transmission window 118.

It should be noted that an outer waveguide 131A of the coaxial waveguide 131 is connected to the antenna body 132 of the disk-shaped form while a central conductor 131B of the coaxial waveguide 131 is connected to the slot plate 135 via an opening formed in the retardation plate 134. Thus, the microwave supplied to the coaxial waveguide 131 is radiated from the slots 135a and 135b while propagating in the radial direction between the antenna body 132 and the slot plate 135.

FIG. 2 shows the slots 135a and 135b formed on the slot plate 135.

Referring to FIG. 2, the slots 135a are formed in a concentric pattern and the slots 135b are formed also in a concentric pattern, wherein each slot 135b is formed for each corresponding slot 135a in a direction perpendicular therewith. The slots 135a and 135b are formed with an interval corresponding to the wavelength of the microwave compressed in the radial direction of the slot plate 135 by the retardation plate 134, and as a result, the microwave is emitted from the slot plate 135 generally in the form of plane wave. Thereby, the slots 135a and 135b are formed in mutually perpendicular relationship, and thus, the microwave thus emitted forms a circularly polarized wave formed of two, mutually perpendicular polarizing components.

Further, the substrate processing apparatus 100 is formed with a cooling water path 133 in the antenna body 132, and the heat accumulated in the microwave transmission window 118 is absorbed via the radial line slot antenna 132.

With the substrate processing apparatus 100 of the present embodiment, a high plasma density is realized over a wide area right underneath the radial line slot antenna 130 and it is possible to carry out uniform plasma processing in short time. Further, the microwave plasma formed with such a process has a low electron temperature because of the plasma excitation achieved by using a microwave, and thus, it becomes possible to avoid damaging or metal contamination of the substrate to be processed. Further, it is possible to excite uniform plasma over a large area substrate, and thus, the substrate processing apparatus 100 can easily attend to the production of semiconductor devices that uses a large diameter semiconductor substrate or production of large-size liquid crystal display devices.

Further, with the substrate processing apparatus 100 of the present embodiment, it is also possible to conduct processes such as ashing, etching, surface modification, surface oxidation, surface nitridation, surface oxynitridation, film formation, and the like.

Meanwhile, when a film formation process is conducted with the substrate processing apparatus 100, there can be a case in which the film formed by the film formation process is adhered also to the parts other than the substrate to be processed in the processing vessel. Further, such adhesion of film can occur also in other surface processing of substrate, such as etching, or the like.

Thus, the substrate processing apparatus 100 of the present embodiment includes a shielding plate 104 inside the processing vessel 101 so as to cover an inner wall surface of the processing vessel 101 or a wall surface of the support part 121. The shielding plate 104 comprises a shield plate 104A disposed so as to cover the inner wall surface of the processing vessel 101 and a shield plate 104B formed so as to cover the wall surface of the support part 121.

By disposing the shielding plate 104, it becomes possible to prevent the adhesion of film on the part other than the substrate W to be processed in the processing vessel 101 such as the inner wall surface of the processing vessel 101 or the wall surface of the support part 121.

Further, the shield plates 104A and 104B are provided respectively with heaters 104a and 104b for enabling heating of the shield plates 104A and 104B.

Thus, when the temperature of the shielding plate 104 is increased as a result of the heating, there is attained the effect of decreasing the amount of the film adhered to the shielding plate 104. In the case of using a hydrocarbon gas or fluorocarbon gas, in particular, the effect of reducing the amount of the film containing carbon on the shielding plate 104 is increased. Thus, it becomes possible to improve the yield of substrate processing by suppressing the particle formation caused by exfoliation of the film. Further, it becomes possible to decrease the cleaning time of the shielding plate and increase the maintenance cycle. With this, it becomes possible to improve the efficiency of the substrate processing.

Now, while the foregoing effects are attained by providing the shielding plate 104, there has been a problem that there are locations in the processing vessel 101 in which it is difficult to remove the adhered film by way of the cleaning process.

For example, it should be noted that the shielding plate 104 is disposed so as to divide the space inside the processing vessel 101 into a first space 102 formed between the shielding plate 104 and the stage 120 and a second space 103 formed in the gap between the shielding plate 104 and the inner wall surface of the processing vessel 101 or in the gap between the shielding plate 104 and the wall surface of the support part 121. More specifically, the second space 103A is formed between the shield plate 104A of the shielding plate 104 and the inner wall surface of the processing vessel 101 and the second space 103B is formed between the shielding plate 104B and the support part 121. Thereby, the second space 103 includes the second spaces 103A and 103B.

With conventional substrate processing apparatuses, there has been a case, when there is formed a narrow space corresponding the second processing space 103 noted above, that deposits are formed in the narrow space and becomes the source of particles. This is because it has been difficult to supply a cleaning gas efficiently into such a narrow space with the conventional substrate processing apparatuses.

Thus, according to the substrate processing apparatus 100 of the present embodiment, there are provided a first evacuation path for evacuating the first space 102 and a second evacuation path for evacuating the second space 103, such that the first evacuation path and the second evacuation path are independent with each other. With such a construction, the evacuation efficiency of the second space 103 is improved and it becomes possible to supply the cleaning gas efficiently to the second space.

Thus, it becomes possible to remove the deposits such as the film adhered to the second space 103 at the time of the substrate processing efficiently, and it becomes possible to improve the yield of substrate processing while suppressing the particle formation. Further, it becomes possible to reduce the cleaning time of the processing vessel. Further, the maintenance cycle of the processing vessel is increased and the efficiency of substrate processing is improved.

Next, the construction of the respective evacuation paths for evacuating the first space 102 and the second space 103 will be explained.

The first evacuation path for evacuating the first space 102 is formed around the stage 120 so as to be surrounded by the shielding plate 104 and includes first evacuation ports 141 provided in plural number on a bottom surface, for example, of the processing vessel 101.

The first evacuation ports 141 are connected with an evacuation line 142 that serves for the first evacuation path and has a construction in which the gases such as the plasma gas, processing gas, or the like, supplied to the first space 102 are evacuated from the first evacuation ports 141 via the evacuation line 142.

On the other hand, the second evacuation path for evacuating the second processing space 103A formed in the gap between the inner wall surface of the processing vessel 101 and the shield plate 104A has a construction of including a second evacuation port 105 formed on the inner wall surface of the processing vessel 101 so as to face the second space 103A. Similarly, the second evacuation path formed in the gap between the support part 121 and the shield plate 104B for evacuating the second processing space 103B has a construction of including a second evacuation port 106 formed on the inner wall surface of the processing vessel 101 so as to face the second space 103B.

Each of the second evacuation port 105 and the second evacuation port 106 has a structure that communicates with an evacuation groove 107 or an evacuation groove 108 formed inside a wall part of the processing vessel 101 that defines the space inside the processing vessel 101, wherein the evacuation grooves constitute the second evacuation path.

The evacuation grooves 107 and 108 are formed so as to extend inside the wall part of the processing vessel 101 and merges with each other in the wall part, wherein the evacuation grooves 107 and 108 are connected to the evacuation line 109 provided to the processing vessel 101. Thus, the second space 103 is evacuated via the evacuation line 109. Further, the evacuation groove 108 is formed so as to merge with the evacuation groove 107 while avoiding the evacuation line 142 such that there is caused no communication between the evacuation groove 108 and the evacuation line 142.

Thus, according to the substrate processing apparatus of the present embodiment, in which the first evacuation port for evacuating the first processing space 102 and the second evacuation port for evacuating the second processing space 103 are provided independently, it becomes possible to improve the evacuation efficiency of the second space 103.

Thus, it becomes possible, in the case of cleaning the interior of the processing vessel 101 by a cleaning gas (includes a plasma-excited cleaning gas), to supply the cleaning gas to the second processing space 103 efficiently, and the efficiency of cleaning the deposits, such as a film deposited in the space formed in the gap behind the shielding plate and cleaning thereof has been difficult conventionally, is improved.

Further, it should be noted that the evacuation line 109 and the evacuation line 142 are both connected to the evacuation line 112, and the evacuation line 112 is connected to evacuation means 113 such as a turbo molecular pump. With the substrate processing apparatus of the present embodiment, there is further provided evacuation path switching means capable of switching the evacuation path for evacuating the interior of the processing vessel 101 between the first evacuation path and the second evacuation path, and because of this, it becomes possible to supply the cleaning gas to the second space 103 efficiently.

The evacuation path switching means comprises a first valve 111 provided so as to be able to disconnect the evacuation line 142 and a second valve 110 provided so as to be able to disconnect the evacuation line 109. Thus, by closing the valve 110 and opening the valve 111 and disconnecting the evacuation line 109, the interior of the processing vessel 101 is evacuated by the evacuation means 113 via the first evacuation path, and hence via the first evacuation port 141 and the evacuation line 142.

Further, when the valve 110 is opened and the valve 111 is closed such that the evacuation line 142 is disconnected, the interior of the processing vessel 101 is evacuated by the evacuation means 113 via the second evacuation path, and hence via the second evacuation ports 105 and 106, the evacuation grooves 107 and 108 and further via the evacuation line 109.

Thus, by switching the evacuation path by the evacuation switching means, it becomes possible to evacuate the interior of the processing vessel efficiently and it becomes further possible to conduct the cleaning process efficiently. For example, it is preferable to evacuate the interior of the processing vessel via the first evacuation path of large evacuation conductance when the substrate processing is to be achieved, while in the case of conducting the cleaning of the interior of the processing vessel, it is preferable to use the first evacuation path or the second evacuation path appropriately according to the needs.

For example, it is preferable to evacuate the cleaning gas from the first evacuation path of large evacuation conductance in the case of conducting the cleaning of the film deposited in the part of the processing vessel 101 that faces the first space 102 of large volume.

In the case of conducting the cleaning of the film deposited in the part of the processing vessel 101 facing the second space 103, on the other hand, it is preferable to evacuate the cleaning gas from the second evacuation path so that the second space 103 is evacuated efficiently and the cleaning gas is supplied to the second space 103 efficiently.

Further, the cleaning of the processing space 101 may be conducted by any of the method that conducts the cleaning each time the film formation processing is made to one substrate to be processed or the method that conducts the cleaning after conducting the film forming processing to plural substrates to be processed. Further, it is possible to conduct the cleaning while changing the number of the cleaning processes or changing the interval of the cleaning in each of the first space 102 and the second space 103.

Further, it is also possible to open both the valve 110 and the valve 111 and evacuate the cleaning gas via both of the first path and the second path.

Further, with the present embodiment, it should be noted that a variable conductance valve is used for the valve 111 for enabling the adjustment of the evacuation conductance. Because of use of such a variable conductance valve, it is possible to control the pressure inside the processing vessel arbitrarily at the time of evacuating the processing vessel via the first evacuation path by changing the conductance of the variable conductance valve. In the case of using such a variable conductance valve, it is difficult to disconnect the evacuation path perfectly, and there appears a valve leakage with an amount much larger than in the case of using ordinary diaphragm valve. Even in such a case, the amount of the gas leaked through the valve is trifle and it can be regarded that the evacuation path is disconnected substantially.

Further, it is possible to use a diaphragm valve, or the like, for the valve 110. Further, it is possible to use a variable conductance valve for the valve 110.

Further, it should be noted that control of the gas supply amount, opening and closing of the gas valves, opening and closing of the evacuation valves, conductance of the evacuation path, heater temperature, microwave power, and the like, is achieved with the substrate processing apparatus 100 of the present embodiment by a control unit 200.

Next, an example of detailed film forming condition will be presented below for the case of a plasma CVD process, which is an exemplary substrate processing conducted by the substrate processing apparatus 100.

With this example, Ar and C₄F₆ are supplied to the processing vessel 101 respectively from the plasma gas supplying ring 115 and the processing gas supplying part with a flow rate of 200 sccm for Ar and 100 sccm for C₄F₆, and microwave plasma is excited in the processing vessel by supplying a microwave power of 2000 W to the radial line slot antenna 130. In this case, a film of CFx can be formed on the substrate to be processed with a film forming rate of 100 nm/m. In this case, it is preferable to use the first evacuation path for the evacuation path of the processing vessel.

Further, an example of the cleaning condition of the processing vessel for the case of conducting the foregoing film forming processing will be shown below.

With this process, Ar and O₂ are supplied respectively from the plasma gas supplying ring 115 and the processing gas supplying part to the processing vessel 101 with the flow rate of 200 sccm for Ar and 300 sccm for O₂, and microwave plasma is excited in the processing vessel by supplying a microwave power of 3000 W to the radial line slot antenna 130. With this, the cleaning gas is dissociated and active species such as radicals needed for the cleaning process are formed. Thus, the cleaning of the processing vessel is conducted. Here, it is preferable to use both of the fist and second evacuation paths by switching the evacuation path of the processing vessel between the first evacuation path and the second evacuation path.

### EMBODIMENT 2

Further, the substrate processing apparatus of the present invention is not limited to the substrate processing apparatus 100 described with reference to Embodiment 1, but various variations and modifications are possible.

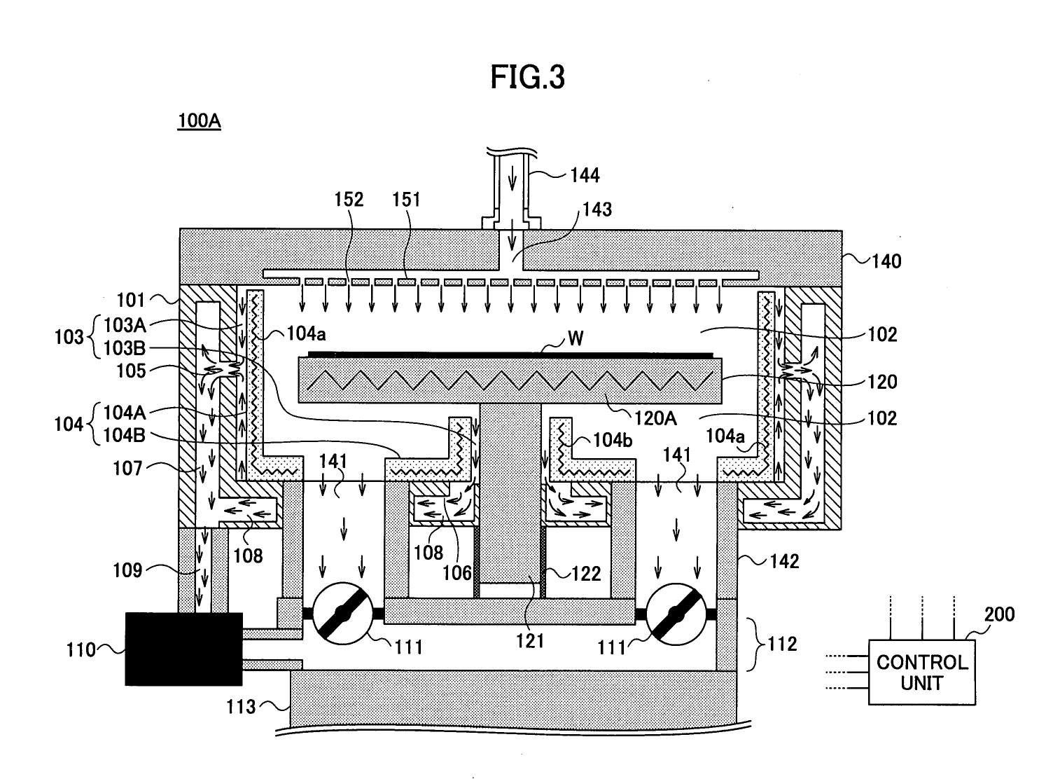

FIG. 3 is a schematic cross-sectional diagram showing a substrate processing apparatus 100A according to Embodiment 2 of the present invention schematically. In the drawing, those parts corresponding to the parts described previously are designated by the same reference numerals and the description thereof will be omitted.

Referring to FIG. 3, the substrate processing apparatus 100A lacks the radial line slot antenna 130, the antenna flange 117, the transmission window support part 116 and the microwave transmission window 118 used with Embodiment 1, and a showerhead 140 is provided instead on the processing vessel 101.

The showerhead 140 is provided so as to cover the opening of the processing vessel 101 wherein the showerhead 140 is formed with a gas groove 151 in which the processing gas causes diffusion, and there are formed plural gas apertures 152 in communication with the gas groove 151 and with the first space 102 for supplying the processing gas to the processing vessel. Further, a gas groove 143 connected to the gas supply line 144 is connected to the gas groove 151 for supplying the processing gas.

In the case of the substrate processing apparatus 100A of the present embodiment, a heater 120A is embedded in the stage 120 for heating the substrate W to be processed and placed on the stage 120, and the substrate processing apparatus 100A has a construction capable of heating the substrate W to a high temperature such as 500° C. or higher.

Thus, it is possible with the present embodiment to carry out a thermal CVD process by decomposing the processing gas supplied from the showerhead 140 thermally on the substrate W to be processed.

In this case, the cleaning can be conducted by a gas cleaning process that uses a reactive gas.

Further, it should be noted that the present invention can be changed or modified variously in addition to those shown in the drawing. For example, the present invention is applicable to parallel-plate type plasma processing apparatuses, high-density plasma processing apparatuses (plasma processing apparatus of ICP, ECR, helicon, or the like), or the like.

Further, while the present invention has been explained heretofore with reference to preferred embodiments, the present invention is by no means limited to such specific embodiments and various variations and modifications may be made without departing from the scope of the invention set forth in the claims.

### INDUSTRIAL APPLICABILITY

According to the present invention, it becomes possible to improve the efficiency of cleaning in a substrate processing apparatus.

1. A substrate processing apparatus, comprising:
a processing vessel holding therein a substrate to be processed;
gas supplying means for supplying a gas for processing into said processing vessel;
a stage provided in the processing vessel for holding said substrate to be processed;
a shielding plate dividing a space inside said processing vessel into a first space and a second space, characterized in that there are provided:
a first evacuation path for evacuating said first space; and
a second evacuation path for evacuating said second space.

2. The substrate processing apparatus as claimed in claim 1, wherein said first space is a space formed between said stage and said shielding plate.

3. The substrate processing apparatus as claimed in claim 1, wherein said second space includes a space formed between said shielding plate and an inner wall surface of said processing vessel.

4. The substrate processing apparatus as claimed in claim 1, wherein said second space includes a space formed between said shielding plate and a support part supporting said stage.

5. The substrate processing apparatus as claimed in claim 1, further comprising an evacuation path switching means enabling switching between said first evacuation path and said second evacuation path for an evacuation path evacuating said processing vessel.

6. The substrate processing apparatus as claimed n claim 5, wherein said evacuation path switching means comprises a first valve provided to said first evacuation path and a second valve provided to said second evacuation path.

7. The substrate processing apparatus as claimed in claim 6, wherein said first valve comprises a variable conductance valve capable of adjusting an evacuation conductance.

8. The substrate processing apparatus as claimed in claim 1, wherein said first evacuation path comprises a first evacuation port provided to said processing vessel and said second evacuation path comprises a second evacuation port provided to said processing vessel independently to said first evacuation port.

9. The substrate processing apparatus as claimed in claim 1, wherein said second evacuation path includes an evacuation groove provided inside a wall part of said processing vessel defining a space inside said processing vessel.

10. The substrate processing apparatus as claimed in claim 1, wherein there is provided plasma excitation means in said processing vessel for exciting plasma.

11. The substrate processing apparatus as claimed in claim 10, wherein said plasma excitation means comprises a radial line slot antenna provided on said processing vessel.

12. The substrate processing apparatus as claimed in claim 1, wherein said gas supplying means comprises first gas supplying means and second gas supplying means, said second gas supplying means supplying a gas in said processing vessel independently from said first gas supplying means.

13. The substrate processing apparatus as claimed in claim 1, wherein said shielding plate is provided with heating means for heating said shielding plate.
